(19) United States
(12) Patent Application Publication
(10) Pub. No.: US 2026/0173370 A1
(43) Pub. Date: Jun. 18, 2026

(54) ERASABLE PROGRAMMABLE NON-VOLATILE MEMORY CELL

(71) Applicant: eMemory Technology Inc., Hsin-Chu (TW)

(72) Inventors: Wein-Town SUN, Hsinchu County (TW); Woan-Yun HSIAO, Hsinchu County (TW); Siao-Cheng YAN, Hsinchu County (TW)

(21) Appl. No.: 19/419,181

(22) Filed: Dec. 15, 2025

Related U.S. Application Data
(60) Provisional application No. 63/734,217, filed on Dec. 16, 2024.

(51) Int. Cl. H10B 41/70; G11C 16/04; H10B 41/35

(52) U.S. Cl. CPC H10B 41/70; G11C 16/0441; H10B 41/35

(57) ABSTRACT

An erasable programmable non-volatile memory cell includes a well region, a first gate structure, a second gate structure, a first merged doped region, a second merged doped region and a lightly doped drain region. The first merged doped region is located beside a first side of the first gate structure. The lightly doped drain region is located beside a second side of the first gate structure and a first side of the second gate structure. The second merged doped region is located beside a second side of the second gate structure. The first merged doped region, the first gate structure and the lightly doped drain region are collaboratively formed as a select transistor. The lightly doped drain region, the second gate structure and the second merged doped region are collaboratively formed as a floating gate transistor.

This application claims the benefit of U.S. provisional application Ser. No. 63/734,217, filed Dec. 16, 2024, the subject matters of which is incorporated herein by reference.

### FIELD OF THE INVENTION

The present invention relates to a non-volatile memory cell, and more particularly to an erasable programmable non-volatile memory cell.

### BACKGROUND OF THE INVENTION

FIG. 1A is a schematic top view of a conventional erasable programmable non-volatile memory cell. FIG. 1B is a schematic circuit diagram illustrating the equivalent circuit of the erasable programmable non-volatile memory cell shown in FIG. 1A. For example, the erasable programmable non-volatile memory cell is disclosed in U.S. Pat. No. 11,049,564 B2. For brevity, the erasable programmable non-volatile memory cell 450 will be referred hereinafter to as a memory cell.

The memory cell 450 includes two serially-connected p-type transistors. These two p-type transistors are constructed in an N-well region NW. Three p-type doped regions 451, 452 and 453 are formed in the N-well region NW. In addition, two polysilicon gates 454 and 455 are formed over the areas between the three p-type doped regions 451, 452 and 453.

The first p-type transistor is used as a select transistor M_{S}. Moreover, the first p-type transistor includes a select gate 454, the p-type doped region 451 and the p-type doped region 452. The select gate 454 is served as a word line WL1. The p-type doped region 451 is connected to a source line SL1.

The second p-type transistor is used as a floating gate transistor M_{F}. Moreover, the second p-type transistor includes a floating gate 455, the p-type doped region 452 and the p-type doped region 453. The p-type doped region 453 is connected to a bit line BL1.

The floating gate 455 is extended externally to the top side of the n-type doped region 456 through the N-well region NW and the P-well region PW to cover the n-type doped region 456. Consequently, an erase gate region 460 is defined. The n-type doped region 456 is connected to an erase line EL1. The erase gate region 460 and the floating gate 455 are collaboratively formed as a capacitor C. Optionally, a p-type block region PWBLK is formed between the P-well region PW and the n-type doped region 456.

As shown in FIG. 1B, the memory cell 450 includes a select transistor M_{S}, a floating gate M_{F} and a capacitor C. The first drain/source terminal of the select transistor M_{S} is connected to the source line SL1. The gate terminal of the select transistor M_{S} is connected to the word line WL1. The first drain/source terminal of the floating gate transistor M_{F} is connected to the second drain/source terminal of the select transistor M_{S}. The second drain/source terminal of the floating gate transistor M_{F} is connected to a bit line BL1. The first terminal of the capacitor C is connected to the floating gate 455 of the floating gate transistor MF. The second terminal of the capacitor C is connected to the erase line EL1.

Generally, the floating gate 455 of the memory cell 450 can store carriers, e.g., electrons. When a program action is performed, a program voltage is provided. Consequently, carriers are injected into the floating gate 455, the memory cell 450 is in a programmed state. For example, the program voltage is about 7.5V to 9V.

The erase gate region 460 of the memory cell 450 is used to eject carriers. When an erase action is performed, an erase voltage is provided. Consequently, carriers are ejected from the floating gate 455 to the erase line EL1 through the erase gate region 460, and the memory cell 450 is in an erased state. For example, the erase voltage is about 14V to 19V.

From the top view of the conventional memory cell 450, the floating gate 455 is extended externally to the erase gate region 460 that is formed by the n-type doped region 456. The erase gate region 460 occupies approximately one third of the area of the memory cell 450.

### SUMMARY OF THE INVENTION

An embodiment of the present invention provides an erasable programmable non-volatile memory cell. The erasable programmable non-volatile memory cell includes a first well region, a first gate structure, a second gate structure, a first spacer, a second spacer, a first lightly doped drain region, a first merged doped region, a second merged doped region, a metal layer, a source line, a word line, a bit line and an assist line. The first well region is formed in a surface of a semiconductor substrate. The first gate structure and the second gate structure are formed on the first well region. The first gate structure is located beside a first side of the second gate structure. The first gate structure includes a first extension segment. The first extension segment is located beside a second side of the second gate structure. The first spacer is in contact with a sidewall of the first gate structure. The second spacer is in contact with a sidewall of the second gate structure. The first spacer and the second spacer are overlapped with each other in a region between the first gate structure and the second gate structure. The first lightly doped drain region is formed in the first well region. The first merged doped region and the second merged doped region are formed in the first well region. The first merged doped region is located beside a first side of the first gate structure. The first lightly doped drain region is located beside a second side of the first gate structure and a first side of the second gate structure. The second merged doped region is located beside a second side of the second gate structure. The metal layer is formed over the second gate structure. The source line is electrically connected with the first merged doped region. The word line is electrically connected with the first gate structure. The bit line is electrically connected with the second merged doped region. The assist line is electrically connected with the metal layer. The second gate structure and the metal layer are collaboratively formed as a first plate capacitor. A first terminal of the first plate capacitor is electrically connected to the assist line. A second terminal of the first plate capacitor is electrically connected to the second gate structure. The first gate structure and the second gate structure are collaboratively formed as a second plate capacitor. A first terminal of the second plate capacitor is electrically connected to the word line. A second terminal of the second plate capacitor is electrically connected to the second gate structure. The first merged doped region, the first gate structure and the first lightly doped drain region are collaboratively formed as a select transistor. The first lightly doped drain region, the second gate structure and the second merged doped region are collaboratively formed as a floating gate transistor.

Numerous objects, features and advantages of the present invention will be readily apparent upon a reading of the following detailed description of embodiments of the present invention when taken in conjunction with the accompanying drawings. However, the drawings employed herein are for the purpose of descriptions and should not be regarded as limiting.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1A (prior art) is a schematic top view of a conventional erasable programmable non-volatile memory cell;

FIG. 1B (prior art) is a schematic circuit diagram illustrating the equivalent circuit of the erasable programmable non-volatile memory cell shown in FIG. 1A;

FIGS. 2A to 2J schematically illustrate the steps of a method of manufacturing an erasable programmable non-volatile memory cell according to a first embodiment of the present invention;

FIG. 2K is a schematic equivalent circuit diagram of the erasable programmable non-volatile memory cell according to the first embodiment of the present invention;

FIG. 3A is a bias voltage table illustrating the bias voltages for performing a program action, an erase action and a read action on the memory cell according to the first embodiment of the present invention;

FIG. 3B is a schematic circuit diagram illustrating the operations of performing the program action on the memory cell of the first embodiment through a channel hot electron (CHE) effect;

FIG. 3C is a schematic circuit diagram illustrating the operations of performing the erase action on the memory cell of the first embodiment through a channel hot hole (CHH) effect;

FIG. 3D is a schematic circuit diagram illustrating the operations of performing the erase action on the memory cell of the first embodiment through a band-to-band hot hole (BBHH) effect;

FIG. 3E is a schematic circuit diagram illustrating the operations of performing the read action on the memory cell of the first embodiment;

FIG. 4 is a schematic top view illustrating an erasable programmable non-volatile memory cell according to a second embodiment of the present invention;

FIG. 5 is a schematic top view illustrating an erasable programmable non-volatile memory cell according to a third embodiment of the present invention; and

FIGS. 6A to 6I schematically illustrate the steps of a method of manufacturing an erasable programmable non-volatile memory cell according to a fourth embodiment of the present invention.

### DETAILED DESCRIPTION OF PREFERRED EMBODIMENTS

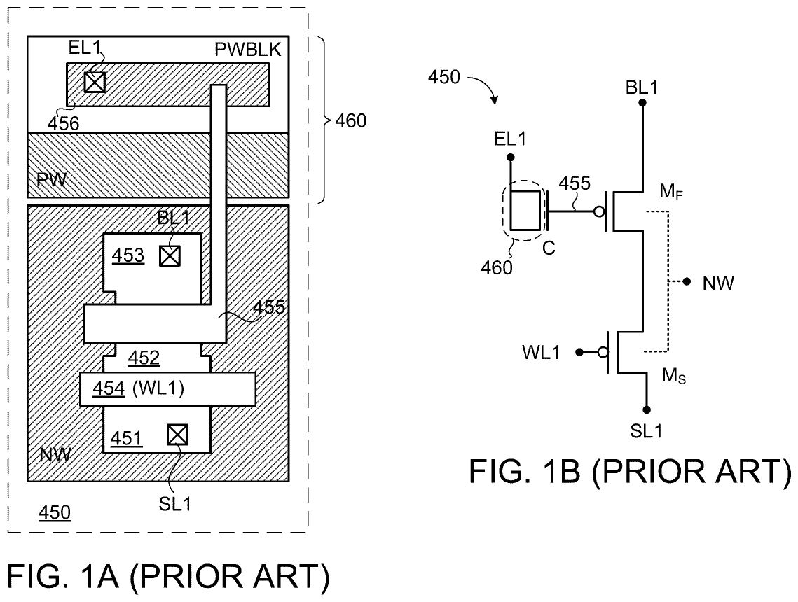

The present invention provides an erasable programmable non-volatile memory cell. The erase gate region 460 in the memory cell 450 of FIG. 1A is not designed in the erasable programmable non-volatile memory cell of the present invention. Consequently, the size of the erasable programmable non-volatile memory cell is reduced. For example, the layout area can be reduced by at least 30%.

Generally, in the CMOS manufacturing process, MV devices and LV devices are formed on a single piece of semiconductor substrate. The present invention provides an erasable programmable non-volatile memory cell. By using the manufacturing method including a medium voltage (MV) production procedure and a low voltage (LV) production procedure, the erasable programmable non-volatile memory cell is manufactured. That is, for designing the structure of the erasable programmable non-volatile memory cell of the present invention, a portion of the structure is manufactured according to the design rule of the MV device, and another portion of the structure is manufactured according to the design rule of the LV device. Consequently, the size of the erasable programmable non-volatile memory cell will be reduced, and the program voltage and the erase voltage provided to the memory cell will be decreased. For well understanding the concepts of the present invention, some embodiments of the memory cell will be described as follows.

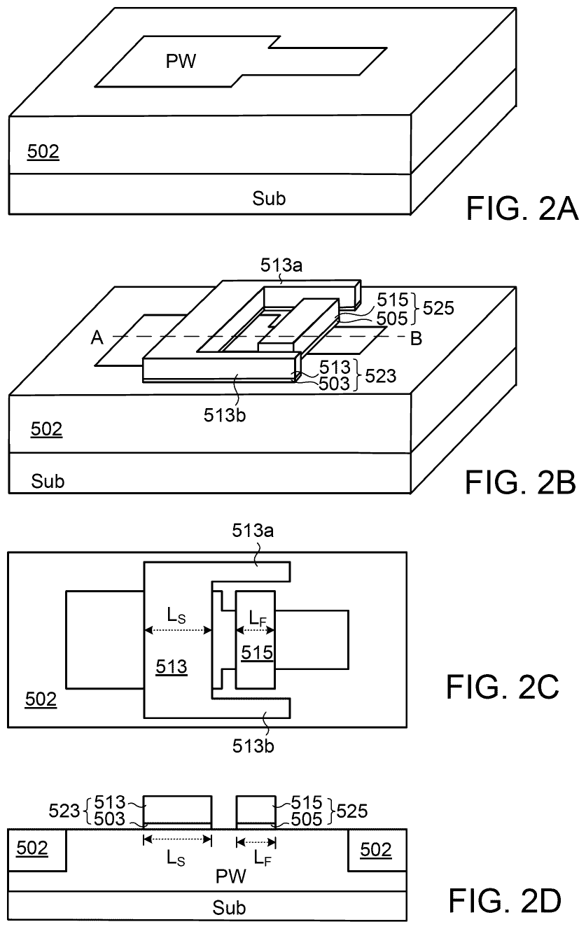

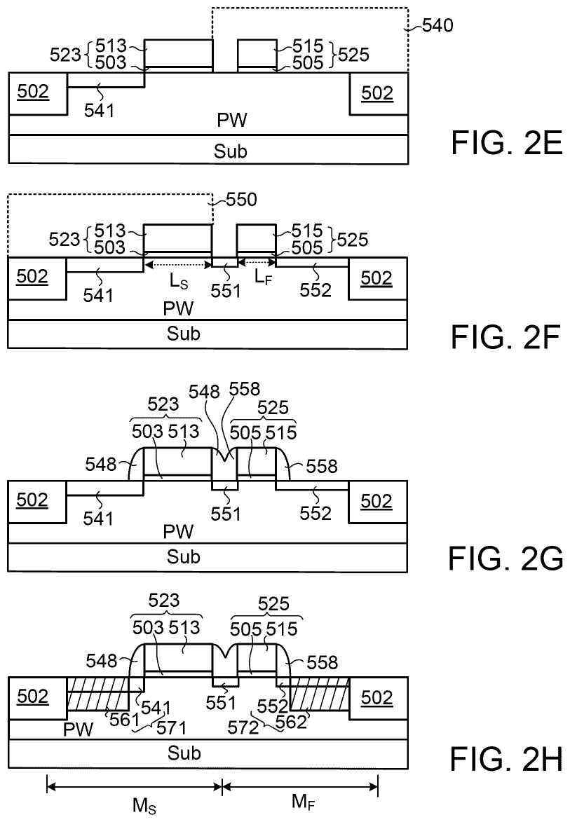

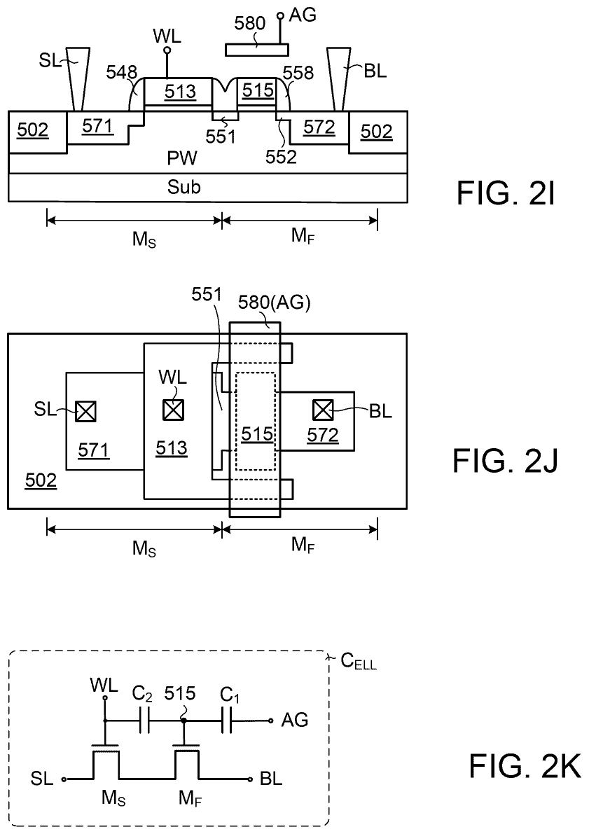

FIGS. 2A to 2J schematically illustrate the steps of a method of manufacturing an erasable programmable non-volatile memory cell according to a first embodiment of the present invention. FIG. 2K is a schematic equivalent circuit diagram of the erasable programmable non-volatile memory cell according to the first embodiment of the present invention. For brevity, the erasable programmable non-volatile memory cell will be referred hereinafter to as a memory cell.

As shown in FIG. 2A, an isolation structure forming step is performed. An isolation structure 502 is formed on a semiconductor substrate Sub. Due to the isolation structure 502, a first region is defined. The semiconductor substrate Sub is covered by the isolation structure 502. The surface of the semiconductor substrate Sub corresponding to the first region is exposed. Then, a well region forming step is performed. A first well region is formed in the surface of the semiconductor substrate Sub corresponding to the first region. For example, the isolation structure 502 is a shallow trench isolation (STI) structure, and the first well region is a P-well region.

Then, a gate structure forming step is performed. As shown in FIG. 2B, two gate structures 523 and 525 are formed on the surface of the P-well region. The first region is divided into three sub-regions by the two gate structures 523 and 525. In addition, the gate structure 523 and the gate structure 525 are not contacted with each other.

The gate structure 523 includes a gate dielectric layer 503 and a polysilicon gate layer 513. The gate structure 525 includes a gate dielectric layer 505 and a polysilicon gate layer 515. The gate dielectric layers 503 and 505 are contacted with the P-well region PW. The polysilicon gate layer 513 is contacted with the gate dielectric layer 503. The polysilicon gate layer 515 is contacted with the gate dielectric layer 505.

Please refer to FIG. 2C and FIG. 2D. FIG. 2C is a schematic top view illustrating the resulting structure of FIG. 2B. FIG. 2D is a schematic cross-sectional view illustrating the resulting structure of FIG. 2B and taken along the dotted lines AB. For example, the gate structure 525 is a rectangular gate structure, and the gate structure 523 is a C-shaped gate structure. In other words, the gate structure 523 includes two extension segments.

Take the polysilicon gate layer 513 for example. The polysilicon gate layer 513 is located beside a first side of the polysilicon gate layer 515. Furthermore, the polysilicon gate layer 513 includes two extension segments 513a and 513b. The extension segment 513a is located over the isolation structure 502 and extends to a second side of the polysilicon gate layer 515. The extension segment 513b is located over the isolation structure 502 and extended to a third side of the polysilicon gate layer 515. That is, the polysilicon gate layer 513 is located beside three sides of the polysilicon gate layer 515.

In an embodiment, the distance between the two gate structures 523 and 525 is designed according to a poly-to-poly minimum rule. That is, the distance between the two polysilicon gate layers 513 and 515 is shortened as much as possible, and they are not in contact with each other. Consequently, the two gate structures 523 and 525 are collaboratively formed as a plate capacitor. In other words, the polysilicon gate layer 513 of the gate structure 523 and the polysilicon gate layer 515 of the gate structure 525 are collaboratively formed as a poly/poly plate capacitor.

The polysilicon gate layer 515 of the gate structure 525 is served as a floating gate of a floating gate transistor. The polysilicon gate layer 513 of the gate structure 523 is served as a select gate of a select transistor. In this embodiment, the channel length L_{F} of the floating gate transistor is smaller than the channel length L_{S} of the select transistor, i.e., L_{F}<L_{S}. For example, the channel length L_{S} of the select transistor is 0.55 μm, and the channel length L_{F} of the floating gate transistor is 0.35 μm.

Please refer to FIG. 2E. Then, the gate structure 525 and its two side areas are covered with a mask 540 shown in dotted lines. For example, the part of the surface between the gate structure 523 and the gate structure 525 is covered by the mask 540, the part of the surface on the right side of the gate structure 525 is covered by the mask 540, but the part of the surface on the left side of the gate structure 523 is not covered by the mask 540. Then, a lightly doped drain process (LDD process) in the MV production procedure is performed. Consequently, an n-type lightly doped drain region (n-LDD region) 541 is formed in the surface of the P-well region PW uncovered by the mask 540. The n-LDD region 541 is formed under the surface of the P-well region PW and located beside a side (e.g., a left side) of the gate structure 523.

Please refer to FIG. 2F. After the mask 540 is removed, the gate structure 523 and its left side region are covered with a mask 550 shown in dotted lines. In other words, the region previously covered by mask 540 is exposed. Then, an LDD process in the LV production procedure is performed. Consequently, n-type lightly doped drain regions (n-LDD regions) 551 and 552 are formed in the surface of the P-well region PW uncovered by the mask 550. The n-LDD regions 551 and 552 are formed under the surface of the P-well region PW and respectively located beside the two sides of the gate structure 525. The doping concentrations of the n-LDD regions 551 and 552 are equal, and the doping depths of the n-LDD regions 551 and 552 are equal.

The region between the n-LDD region 541 and the n-LDD region 551 is served as a channel region of the select transistor, and the length of the channel region is L_{S}. The region between the n-LDD region 551 and the n-LDD region 552 is served as a channel region of the floating gate transistor, and the distance of the channel region is L_{F}. In this embodiment, the channel length L_{F} of the floating gate transistor is smaller than the channel length L_{S} of the select transistor, i.e., L_{F}<L_{S}.

The first LDD process belongs to the MV production procedure. The second LDD process belongs to the LV production procedure. In other words, the doping concentration of the n-LDD region 541 is less than the doping concentrations of the n-LDD regions 551 and 552, and the doping depth of the n-LDD region 541 is deeper than the doping depth of the n-LDD regions 551 and 552.

Please refer to FIG. 2G. After the mask 550 is removed, a spacer 548 is formed on the sidewall of the gate structure 523, and a spacer 558 is formed on the sidewall of the gate structure 525. In this embodiment, the distance between the two gate structures 523 and 525 is very short, and thus the two spacers 548 and 558 between the two gate structures 523 and 525 are overlapped with each other. That is, the n-LDD region 551 between the two gate structures 523 and 525 is completely covered by the two spacers 548 and 558.

Please refer to FIG. 2H. Then, an n-type ion implantation process is performed on the surface of the semiconductor substrate Sub by using the two gate structures 523 and 525 and the two spacers 548 and 558 as masks. Consequently, two n-type ion implantation regions 561 and 562 shown in oblique lines are formed in the sub-regions uncovered by the two gate structures 523 and 525 and the two spacers 548 and 558. Especially, the n-type ion implantation regions 561 and 562 have the highest doping concentration, and their dopant concentration is higher than the dopant concentration of the n-LDD regions 541, 551 and 552.

In some embodiments, the coverage areas of the mask 540 and 55 can be appropriately changed to adjust the dopant concentration and the doping depth of the n-LDD region 551.

For example, in some embodiments, a portion of the n-LDD region 551 has the same dopant concentration as the n-LDD region 541, while another portion of the n-LDD region 551 has the same dopant concentration as the n-LDD region 552. Or, the dopant concentration of the n-LDD region 551 is equal to the sum of the dopant concentrations of the n-LDD region 541 and the n-LDD region 552. Or, the doping depth of the n-LDD region 551 is equal to the doping depth of the n-LDD region 541 or the doping depth of the n-LDD region 552.

Please refer to FIG. 2H again. Then, the n-LDD region 541 and the n-type ion implantation regions 561 are collaboratively formed as a merged n-doped region 571. The merged n-doped region 571 is formed in the surface of the P-well region PW and located beside a first side of the gate structure 523. The n-LDD region 551 is formed in the surface of the P-well region PW between the second side of the gate structure 523 and the first side of the gate structure 525. The n-LDD region 552 and the n-type ion implantation region 562 are collaboratively formed as a merged n-doped region 572. The merged n-doped region 572 is formed in the surface of the P-well region PW under the second side of the gate structure 525.

The gate structure 523, the merged n-doped region 571 on the first side of the gate structure 523 and the n-LDD region 551 on the second side of the gate structure 523 are collaboratively formed as a select transistor M_{S}. In addition, the gate structure 525, the n-LDD region 551 on the first side of the gate structure 525 and the merged n-doped region 572 on the second side of the gate structure 525 are collaboratively formed as a floating gate transistor M_{F}. In this embodiment, the floating gate transistor M_{F} and the select transistor M_{S} are n-type transistors and constructed in the P-well region PW. That is, the body terminals of the floating gate transistor M_{F} and the body terminal of the select transistor M_{S} are connected to the P-well region PW.

Please refer to FIG. 2I. Then, a metal layer 580 is formed over the polysilicon gate layer 515. The size of the metal layer 580 is higher than or equal to the size of the polysilicon gate layer 515. Consequently, the vertical projection area of the metal layer 580 completely covers the polysilicon gate layer 515 of the gate structure 525. It is noted that numerous modifications may be made while retaining the teachings of the present invention. For example, in another example, the size of the metal layer 580 is smaller than the size of the polysilicon gate layer 515. Consequently, the vertical projection area of the metal layer 580 covers a portion of the polysilicon gate layer 515 of the gate structure 525. The polysilicon gate layer 515 and the metal layer 580 are collaboratively formed as a plate capacitor. For example, the polysilicon gate layer 515 and the metal layer 580 are collaboratively formed as a metal/poly plate capacitor.

After a connection step is performed, the memory cell of the first embodiment is completed. For example, the merged n-doped region 571 is connected to a source line SL, the merged n-doped region 572 is connected to a bit line BL, the polysilicon gate layer 513 is connected to a word line WL, and the metal layer 580 is connected to an assist line AG.

FIG. 2J is a schematic top view illustrating the resulting structure of FIG. 2I, in which the spacers are not shown. FIG. 2K is an equivalent circuit of the memory cell shown in FIG. 2I. In this embodiment, the memory cell C_{ELL} includes a select transistor M_{S}, a floating gate transistor M_{F} and a first plate capacitor C₁ and a second plate capacitor C₂. The gate terminal of the select transistor M_{S} is connected to the word line WL. The first drain/source terminal of the select transistor M_{S} is connected to the source line SL. The first drain/source terminal of the floating gate transistor M_{F} is connected to the second drain/source terminal of the select transistor M_{S}. The second drain/source terminal of the floating gate transistor M_{F} is connected to the bit line BL. The first terminal of the first plate capacitor C₁ is connected to the floating gate 515 of the floating gate transistor M_{F}. The second terminal of the first plate capacitor C₁ is connected to the auxiliary line AG. The first terminal of the second plate capacitor C₂ is connected to the floating gate 515 of the floating gate transistor M_{F}. The second terminal of the second plate capacitor C₂ is connected to the word line WL. The second plate capacitor C₂ is a poly/poly plate capacitor. The first plate capacitor C₁ is a metal/poly plate capacitor.

As mentioned above, the memory cell C_{ELL} of the first embodiment includes two transistors M_{F} and M_{S} and two plate capacitors C₁ and C₂. Consequently, the memory cell may be referred to as a 2T2C memory cell. The first plate capacitor C₁ and the second plate capacitor C₂ are used as coupling capacitors. When an erase action is performed, no hot carriers will penetrate the coupling capacitors.

In the memory cell of the first embodiment, the floating gate transistor M_{F} and the select transistor M_{S} are n-type transistors constructed in the P-well region PW. It is noted that numerous modifications may be made while retaining the teachings of the present invention. For example, in another embodiment, the floating gate transistor M_{F} and the select transistor M_{S} are p-type transistors constructed in an N-well region PW.

When compared with the memory cell of FIG. 1A, the floating gate 515 in the memory cell of FIG. 2J is not extended to other areas. Consequently, the size of the memory cell of the present invention can be greatly reduced by about 30% or more. Furthermore, electrons are injected from the channel of the floating gate transistor M_{F} to the floating gate when the conventional memory cell of FIG. 1A is subjected to the program action, and electrons are ejected to the erase line EL1 from the floating gate when the conventional memory cell of FIG. 1A is subjected to the erase action. However, the memory cell of the present invention is not equipped with the erase line. That is, unlike the conventional memory cell, the memory cell of the present invention has no hot carrier ejection path. For performing the program action, the erase action or the read action, the bias voltages to the memory cell of the present invention need to specially designed.

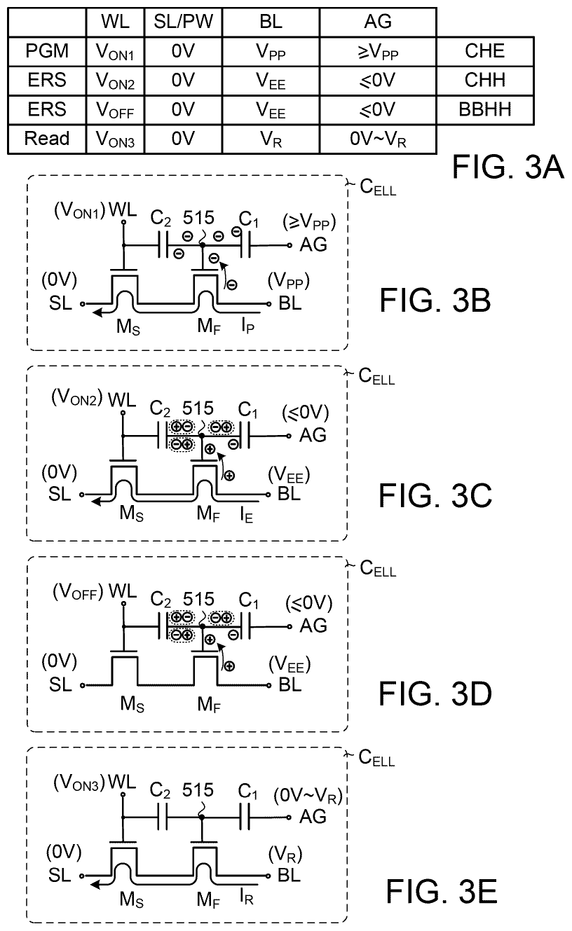

FIG. 3A is a bias voltage table illustrating the bias voltages for performing a program action, an erase action and a read action on the memory cell according to the first embodiment of the present invention. FIG. 3B is a schematic circuit diagram illustrating the operations of performing the program action on the memory cell of the first embodiment through a channel hot electron (CHE) effect. FIG. 3C is a schematic circuit diagram illustrating the operations of performing the erase action on the memory cell of the first embodiment through a channel hot hole (CHH) effect. FIG. 3D is a schematic circuit diagram illustrating the operations of performing the erase action on the memory cell of the first embodiment through a band-to-band hot hole (BBHH) effect. FIG. 3E is a schematic circuit diagram illustrating the operations of performing the read action on the memory cell of the first embodiment. The P-well region PW and the source line SL receive the same bias voltage.

Please refer to FIG. 3A and FIG. 3B. When the program action is performed, the source line SL receives a ground voltage (0V), the word line WL receives a first on voltage V_{ON1}, the bit line BL receives a program voltage V_{PP}, and the assist line AG receives an assist voltage higher than or equal to the program voltage V_{PP}. For example, the program voltage V_{PP} is in the range between 6V and 7V. The first on voltage V_{ON1} is between ⅓×V_{PP} and the program voltage V_{PP}. Obviously, the program voltage V_{PP} for the memory cell of the first embodiment is lower than the program voltage for the conventional memory cell.

When the program action is performed, the select transistor M_{S} is turned on, and a program current I_{P} is generated between the bit line BL the source line SL and. When the hot carriers (e.g., electrons) of the program current I_{P} flow through the pinch point of the channel region of the floating gate transistor MF, electron-hole pairs are generated. Since the electrons are attracted by the voltage from the assist line AG, a channel hot electron (CHE) effect is generated. Consequently, electrons are injected into the floating gate 515. The pinch point is included in the channel region of the floating gate transistor M_{F} and located near the merged n-doped region 572 beside the bit line BL.

Due to the differences between the merged n-doped region 571, the n-LDD regions 551 and the merged n-doped region 572 in the memory cell C_{ELL}, the program voltage V_{PP} can be reduced, and the programming efficiency can be enhanced. In the floating gate transistor M_{F} of the memory cell of FIG. 2I, the n-LDD regions 551 and 552 near the two sides of the floating gate 515 have higher doping concentrations and smaller depths. Furthermore, the floating gate transistor M_{F} has the shorter channel region. Consequently, when the program is performed on the memory cell C_{ELL}, the provision of the lower program voltage V_{PP} can generate a higher electric field at the pinch point of the channel region to increase the programming efficiency. Furthermore, in response to the lower program voltage V_{PP}, the program current I_{P} is lower.

Please refer to FIG. 3A and FIG. 3C. When the erase action is performed, the source line SL receives the ground voltage (0V), the word line WL receives a second on voltage V_{ON2}, the bit line BL receives an erase voltage V_{EE}, and the assist line AG receives a negative voltage. For example, the erase voltage V_{EE} is in the range between 8V and 10V, the second on voltage V_{ON2} is one sixth of the erase voltage (i.e., ⅙×V_{EE}), and the assist line AG receives the negative voltage of −5V. Obviously, the erase voltage V_{EE} provided to the memory cell of the first embodiment is lower than the erase voltage provided to the conventional memory cell.

When the erase action is performed, the select transistor M_{S} is turned on, and an erase current I_{E} is generated between the bit line BL and the source line SL. When the hot carriers (e.g., electrons) of the erase current I_{E} flow through the pinch point of the channel region of the floating gate transistor MF, electron-hole pairs are generated. Since the holes are attracted by the negative voltage from the assist line AG, a channel hot hole (CHH) effect is generated. Consequently, holes are injected into the floating gate 515. After the electron-hole recombination in the floating gate 515, the erase action is completed.

Please refer to FIG. 3A and FIG. 3D. When the erase action is performed, the source line SL receives the ground voltage (0V), the word line WL receives an off voltage V_{OFF}, the bit line BL receives the erase voltage V_{EE}, and the assist line AG receives a negative voltage. For example, the erase voltage V_{EE} is in the range between 8V and 10V, and the off voltage V_{OFF} is a negative voltage. For example, the word line WL and the assist line AG receive the negative voltage of −8V or less.

When the erase action is performed, the select transistor M_{S} is turned off, and no erase current is generated between the bit line BL and the source line SL. Meanwhile, in the floating gate transistor M_{F}, electron-hole pairs are generated at the junction between the merged n-doped region 572 and the P-well region PW. Consequently, a band-to-band hot hole (BBHH) effect is generated. Since holes are attracted by the voltages from the assist line AG and the word line WL, holes are injected into the floating gate 515. After the electron-hole combination in the floating gate 515, the erase action is completed.

Please refer to FIG. 3A and FIG. 3E. When the read action is performed, the source line SL receives the ground voltage (0V), the word line WL receives a third on voltage V_{ON3}, the bit line BL receives a read voltage V_{R}, and the assist line AG receives a voltage between the ground voltage (0V) and the read voltage V_{R}. The magnitude of the third on voltage V_{ON3} is not restricted as long as the third on voltage V_{ON3} is higher than the threshold voltage of the select transistor. The erase voltage V_{EE} is higher than the program voltage V_{PP}. The program voltage V_{PP} is higher than the read voltage V_{R}. The read voltage V_{R} is higher than the ground voltage (0V).

When the read action is performed, the select transistor M_{S} is turned on, and a read current I_{R} is generated between the bit line BL1 and the source line SL. The storage state of the memory cell can be determined according to the magnitude of the read current I_{R}. For example, in case that electrons are stored in the floating gate 515, the magnitude of the read current I_{R} is very low (e.g., nearly zero). Consequently, it is determined that the memory cell is in a programmed state. Whereas, in case that no electrons are stored in the floating gate 515, the magnitude of the read current I_{R} is very high. Under this circumstance, it is determined that the memory cell is in an erased state.

It is noted that structure of the memory cell of the first embodiment may be modified. For example, in another embodiment, the shape of the gate structure 523 in the select transistor M_{S} of the memory cell may be modified to change the structure of the capacitor C₂ while changing the voltage coupling ratio. For example, the gate structure has a G-shaped profile or an L-shaped profile.

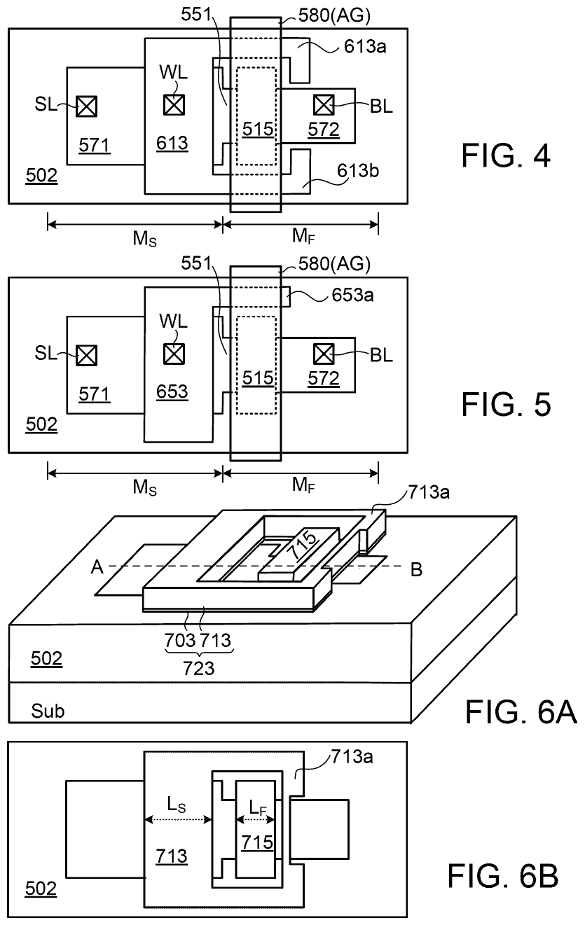

FIG. 4 is a schematic top view illustrating an erasable programmable non-volatile memory cell according to a second embodiment of the present invention. In comparison with the memory cell of the first embodiment, the gate structure in the select transistor M_{S} of the memory cell of this embodiment is a G-shaped gate structure.

In the memory cell of the second embodiment, the polysilicon gate layer 613 is located beside the first side of the polysilicon gate layer 515. The polysilicon gate layer 613 further includes two extension segments 613a and 613b. The extension 613a is located over the isolation structure 502 and extended to the second side of the polysilicon gate layer 515 and a portion of the fourth side of the polysilicon gate layer 515. The extension segment 613b is located over the isolation structure 502 and extended to the third side of the polysilicon gate layer 515 and another portion of the fourth side of the polysilicon gate layer 515. That is, the polysilicon gate layer 613 is located beside three sides of the polysilicon gate layer 515 and a portion of the fourth side of the polysilicon gate layer 515. Consequently, the voltage coupling ratio of the plate capacitor C₂ can be modified.

FIG. 5 is a schematic top view illustrating an erasable programmable non-volatile memory cell according to a third embodiment of the present invention. In comparison with the memory cell of the first embodiment, the gate structure in the select transistor M_{S} of the memory cell of this embodiment is an L-shaped gate structure.

In the memory cell of the third embodiment, the polysilicon gate layer 653 is located beside the first side of the polysilicon gate layer 515. The polysilicon gate layer 653 further includes an extension segment 653a. The extension segment 653a is located over the isolation structure 502 and extended to the second side of the polysilicon gate layer 515. In other words, the polysilicon gate layer 653 is located beside two sides of the polysilicon gate layer 515. Consequently, the voltage coupling ratio of the plate capacitor C₂ can be modified.

The manufacturing process of the memory cell of the second embodiment and the manufacturing process of memory cell of the third embodiment are similar to the manufacturing process of the first embodiment. The equivalent circuit of the memory cell of the second embodiment and the equivalent circuit of the memory cell of the third embodiment is identical to the equivalent circuit of the memory cell of the first embodiment. The voltages of performing the program action, the erase action and the read action on the memory cell of the second embodiment and the memory cell of the third embodiment are similar to those of the memory cell of the first embodiment, and not redundantly described herein.

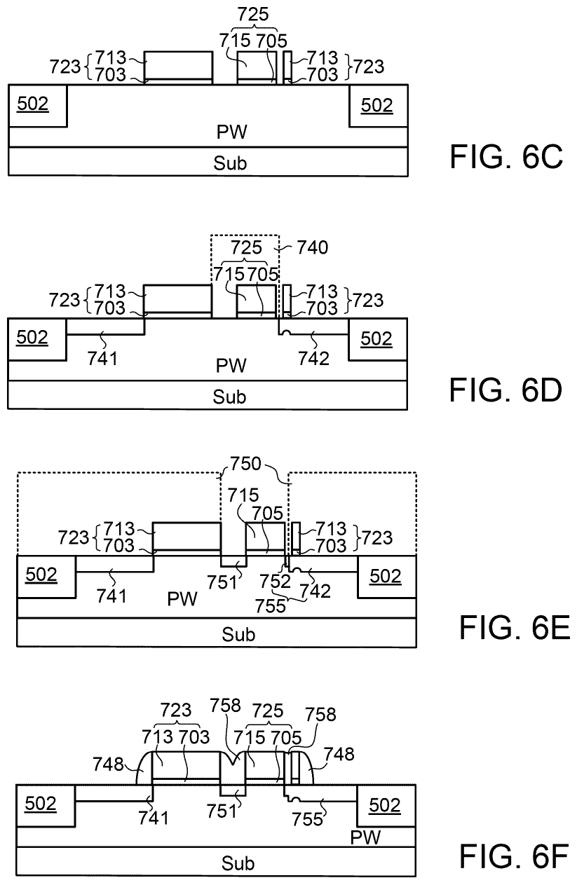

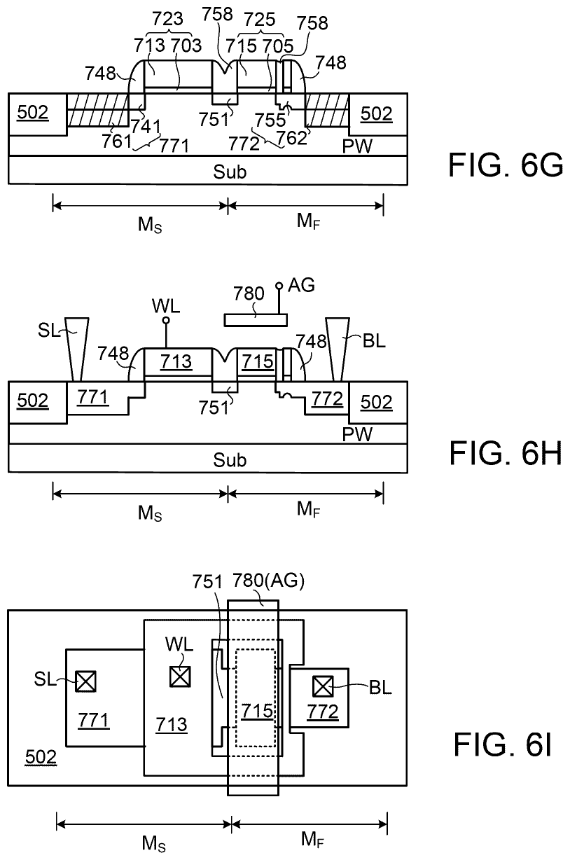

FIGS. 6A to 6I schematically illustrate the steps of a method of manufacturing an erasable programmable non-volatile memory cell according to a fourth embodiment of the present invention. In comparison with the memory cell of the first embodiment, the gate structure of the select transistor M_{S} is distinguished. In this embodiment, the gate structure in the memory cell of this embodiment is an O-shaped gate structure.

Firstly, an isolation structure forming step is performed. An isolation structure 502 is formed on a semiconductor substrate Sub. Due to the isolation structure 502, a first region is defined. The semiconductor substrate Sub is covered by the isolation structure 502. The surface of the semiconductor substrate Sub corresponding to the first region is exposed. Then, a well region forming step is performed. A first well region is formed in the surface of the semiconductor substrate Sub corresponding to the first region.

Then, a gate structure forming step is performed. As shown in FIG. 6A, two gate structures 723 and 725 are formed on the surface of the P-well region. In addition, the gate structure 723 and the gate structure 725 are not contacted with each other.

Please refer to FIG. 6B and FIG. 6C. FIG. 6B is a schematic top view illustrating the resulting structure of FIG. 6A. FIG. 6C is a schematic cross-sectional view illustrating the resulting structure of FIG. 6B and taken along the dotted lines AB. The gate structure 723 includes a gate dielectric layer 703 and a polysilicon gate layer 713. The gate structure 725 includes a gate dielectric layer 705 and a polysilicon gate layer 715. The gate dielectric layers 703 and 705 are contacted with the P-well region PW. The polysilicon gate layer 713 is contacted with the gate dielectric layer 703. The polysilicon gate layer 715 is contacted with the gate dielectric layer 705. For example, the gate structure 725 is a rectangular gate structure, and the gate structure 723 is an O-shaped gate structure. The polysilicon gate layer 713 includes an extension segment 713a. The extension segment 713a is extended from an upper portion of the polysilicon gate layer 713 to a lower portion of the polysilicon gate layer 713. Consequently, the polysilicon gate layer 713 becomes a closed O-shaped polysilicon gate layer 713, and the closed O-shaped polysilicon gate layer 713 surrounds the polysilicon gate layer 715. In other words, the polysilicon gate layer 713 is located beside the four sides of the polysilicon gate layer 715.

In this embodiment, the gate structure 723 beside the right side of the gate structure 725 is very narrow, e.g., about 0.1 μm. Furthermore, the distance between the two polysilicon gate layers 713 and 715 is designed according to a poly-to-poly minimum rule. That is, the distance between the two polysilicon gate layers 713 and 715 is shortened as much as possible, and they are not in contact with each other. Consequently, the polysilicon gate layer 713 and the polysilicon gate layer 715 are collaboratively formed as a poly/poly plate capacitor.

Please refer to FIG. 6D. Then, the gate structure 725 and its two side areas are covered with a mask 740 shown in dotted lines. For example, on the left side of the gate structure 725, the surface between the gate structure 725 and the gate structure 723 is covered by the mask 740. On the right side of the gate structure 725, only a portion of the surface between the gate structure 725 and the gate structure 723 is covered by the mask 740. Then, a lightly doped drain process (LDD process) in the MV production procedure is performed. Consequently, two n-type lightly doped drain regions (n-LDD region) 741 and 742 are formed in the surface of the P-well region PW uncovered by the mask 740. The n-LDD region 741 is formed under the surface of the P-well region PW and located beside the left side of the gate structure 723. The n-LDD region 742 is formed under the surface of the P-well region PW and mainly located beside the right side of the gate structure 723.

Theoretically, two LDD regions will be formed under the surface of the P-well region PW on both sides of the narrow gate structure 723 after the LDD process is performed. However, since the gate structure 723 beside the right side of the gate structure 725 is very narrow, the two LDD regions are merged into the single n-LDD region 742 after the LDD process in the MV production procedure is completed as shown in FIG. 6D.

Please refer to FIG. 6E. After the mask 740 is removed, the O-shaped gate structure 723 and its outside area are covered with a mask 750 shown in dotted lines, and a portion of the inner area of the O-shaped gate structure 723 is also covered with the mask 750. In other words, the region previously covered by mask 740 is exposed. Then, an LDD process in the LV production procedure is performed. Consequently, n-type lightly doped drain regions (n-LDD regions) 751 and 752 are formed in the surface of the P-well region PW uncovered by the mask 750.

The n-LDD regions 751 and 752 are formed under the surface of the P-well region PW and respectively located beside the two sides of the gate structure 725. The doping concentrations of the n-LDD regions 751 and 752 are equal, and the doping depths of the n-LDD regions 751 and 752 are equal. Furthermore, the n-LDD region 752 is contacted with the n-LDD region 742 as shown in FIG. 6E. In other words, the n-LDD region 752 and the n-LDD region 742 are collaboratively formed as a merged n-LDD region 755.

The region between the n-LDD region 741 and the n-LDD region 751 is served as a channel region of the select transistor, and the length of the channel region is L_{S}. The region between the n-LDD region 751 and the merged n-LDD region 755 is served as a channel region of the floating gate transistor, and the distance of the channel region is L_{F}. In this embodiment, the channel length L_{F} of the floating gate transistor is smaller than the channel length L_{S} of the select transistor, i.e., L_{F}<L_{S}.

The first LDD process belongs to the MV production procedure. The second LDD process belongs to the LV production procedure. In other words, the doping concentration of the n-LDD region 741 and 742 is less than the doping concentrations of the n-LDD regions 751 and 752, and the doping depth of the n-LDD region 741 and 742 is deeper than the doping depth of the n-LDD regions 751 and 752.

Please refer to FIG. 6F. After the mask 750 is removed, a spacer 748 is formed on the sidewall of the gate structure 723, and a spacer 758 is formed on the sidewall of the gate structure 725. In this embodiment, the distance between the two gate structures 723 and 725 is very short, and thus the two spacers 748 and 758 between the two gate structures 723 and 725 are overlapped with each other.

Please refer to FIG. 6G. Then, an n-type ion implantation process is performed on the surface of the semiconductor substrate Sub by using the two gate structures 723 and 725 and the two spacers 748 and 758 as masks. Consequently, two n-type ion implantation regions 761 and 762 shown in oblique lines are formed in the sub-regions uncovered by the two gate structures 723 and 725 and the two spacers 748 and 558. Especially, the n-type ion implantation regions 761 and 762 have the highest doping concentration, and their dopant concentration is higher than the dopant concentration of the n-LDD regions 741, 742, 751 and 752.

Please refer to FIG. 6G again. Then, the n-LDD region 741 and the n-type ion implantation regions 761 are collaboratively formed as a merged n-doped region 771. The merged n-doped region 771 is formed in the surface of P-well region PW and located beside a first side of the gate structure 723. The n-LDD region 751 is formed in the surface of the P-well region PW between the second side of the gate structure 723 and the first side of the gate structure 725. The merged n-LDD region 755 and the n-type ion implantation region 762 are collaboratively formed as a merged n-doped region 772. The merged n-doped region 772 is formed in the surface of the P-well region PW under the second side of the gate structure 725.

The gate structure 723, the merged n-doped region 771 on the first side of the gate structure 723 and the n-LDD region 751 on the second side of the gate structure 723 are collaboratively formed as a select transistor M_{S}. In addition, the gate structure 725, the n-LDD region 751 on the first side of the gate structure 725 and the merged n-doped region 772 on the second side of the gate structure 725 are collaboratively formed as a floating gate transistor M_{F}.

Please refer to FIG. 6H and FIG. 6I. FIG. 6I is a schematic top view illustrating the memory cell of FIG. 6I, in which the spacers are not shown. Then, a metal layer 780 is formed over the polysilicon gate layer 715. The size of the metal layer 780 is higher than or equal to the size of the polysilicon gate layer 715. Consequently, the vertical projection area of the metal layer 780 completely covers the polysilicon gate layer 715 of the gate structure 725. It is noted that numerous modifications may be made while retaining the teachings of the present invention. For example, in another example, the size of the metal layer 780 is smaller than the size of the polysilicon gate layer 715. Consequently, the vertical projection area of the metal layer 780 covers a portion of the polysilicon gate layer 715 of the gate structure 725. The polysilicon gate layer 715 and the metal layer 780 are collaboratively formed as a metal/poly plate capacitor.

After a connection step is performed, the memory cell of the fourth embodiment is completed. For example, the merged n-doped region 771 is connected to a source line SL, the merged n-doped region 772 is connected to a bit line BL, the polysilicon gate layer 713 is connected to a word line WL, and the metal layer 780 is connected to an assist line AG.

In the memory cell of the fourth embodiment, the polysilicon gate layer 713 is arranged around the polysilicon gate layer 715. That is, the polysilicon gate layer 713 is located beside four sides of the polysilicon gate layer 715. Consequently, the plate capacitor C₂ composed of the polysilicon gate layer 713 and the polysilicon gate layer 715 has the better voltage coupling ratio.

The equivalent circuit of the memory cell of the fourth embodiment is identical to the equivalent circuit of the memory cell of the first embodiment. The voltages of performing the program action, the erase action and the read action on the memory cell of the second embodiment and the memory cell of the fourth embodiment are similar to those of the memory cell of the first embodiment, and not redundantly described herein.

From the above descriptions, the present invention provides an erasable programmable non-volatile memory cell. In the memory cell, the gate structure of the select transistor is specially designed, and thus at least two sides of the gate structure of the floating gate transistor are located beside the gate structure of the select transistor. Furthermore, the floating gate of the memory of the present invention is not equipped with the extension segment. Consequently, the size of the memory cell is largely reduced.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. An erasable programmable non-volatile memory cell, comprising:
a first well region formed in a surface of a semiconductor substrate;
a first gate structure and a second gate structure formed on the first well region, wherein the first gate structure is located beside a first side of the second gate structure, the first gate structure includes a first extension segment, and the first extension segment is located beside a second side of the second gate structure;
a first spacer and a second spacer, wherein the first spacer is in contact with a sidewall of the first gate structure, and the second spacer is in contact with a sidewall of the second gate structure, wherein the first spacer and the second spacer are overlapped with each other in a region between the first gate structure and the second gate structure;
a first lightly doped drain region formed in the first well region;
a first merged doped region and a second merged doped region formed in the first well region, wherein the first merged doped region is located beside a first side of the first gate structure, the first lightly doped drain region is located beside a second side of the first gate structure and a first side of the second gate structure, and the second merged doped region is located beside a second side of the second gate structure;
a metal layer formed over the second gate structure;
a source line electrically connected with the first merged doped region;
a word line electrically connected with the first gate structure;
a bit line electrically connected with the second merged doped region; and
an assist line electrically connected with the metal layer,
wherein the second gate structure and the metal layer are collaboratively formed as a first plate capacitor, a first terminal of the first plate capacitor is electrically connected to the assist line, and a second terminal of the first plate capacitor is electrically connected to the second gate structure,
wherein the first gate structure and the second gate structure are collaboratively formed as a second plate capacitor, a first terminal of the second plate capacitor is electrically connected to the word line, and a second terminal of the second plate capacitor is electrically connected to the second gate structure,
wherein the first merged doped region, the first gate structure and the first lightly doped drain region are collaboratively formed as a select transistor, and the first lightly doped drain region, the second gate structure and the second merged doped region are collaboratively formed as a floating gate transistor.

2. The erasable programmable non-volatile memory cell as claimed in claim 1, wherein a channel length of the floating gate transistor is smaller than a channel length of the select transistor.

3. The erasable programmable non-volatile memory cell as claimed in claim 1, wherein a vertical projection area of the metal layer covers the second gate structure.

4. The erasable programmable non-volatile memory cell as claimed in claim 1, wherein the first well region is a p-type well region, the first lightly doped drain region is an n-type lightly doped drain region, the first merged doped region is a first merged n-type doped region, and second merged doped region is a second merged n-type doped region.

5. The erasable programmable non-volatile memory cell as claimed in claim 1, wherein the first gate structure includes a first gate dielectric layer and a first polysilicon gate layer, and the second gate structure includes a second gate dielectric layer and a second polysilicon gate layer, wherein the first gate dielectric layer and the second gate dielectric layer are in contact with the first well region, the first polysilicon gate layer is in contact with the first gate dielectric layer, and the second polysilicon gate layer is in contact with the second gate dielectric layer.

6. The erasable programmable non-volatile memory cell as claimed in claim 5, wherein the metal layer and the second polysilicon gate layer are collaboratively formed as the first plate capacitor, and the first plate capacitor is a metal/poly plate capacitor.

7. The erasable programmable non-volatile memory cell as claimed in claim 5, wherein the first polysilicon gate layer and the second polysilicon gate layer are collaboratively formed as the second plate capacitor, and the second plate capacitor is a poly/poly plate capacitor.

8. The erasable programmable non-volatile memory cell as claimed in claim 5, wherein the first polysilicon gate layer is located beside a first side of the second polysilicon gate layer, and the first polysilicon gate layer includes a first extension segment, wherein the first extension segment of the first polysilicon gate layer is located beside a second side of the second polysilicon gate layer.

9. The erasable programmable non-volatile memory cell as claimed in claim 5, wherein the first polysilicon gate layer is located beside a first side of the second polysilicon gate layer, and the first polysilicon gate layer includes a first extension segment and a second extension segment, wherein the first extension segment of the first polysilicon gate layer is located beside a second side of the second polysilicon gate layer, and the second extension segment of the first polysilicon gate layer is located beside a third side of the second polysilicon gate layer.

10. The erasable programmable non-volatile memory cell as claimed in claim 5, wherein the first polysilicon gate layer is located beside a first side of the second polysilicon gate layer, and the first polysilicon gate layer includes a first extension segment and a second extension segment, wherein the first extension segment of the first polysilicon gate layer is located beside a second side of the second polysilicon gate layer and a portion of a third side of the second polysilicon gate layer, and the second extension segment of the first polysilicon gate layer is located beside a fourth side of the second polysilicon gate layer and another portion of the third side of the second polysilicon gate layer.

11. The erasable programmable non-volatile memory cell as claimed in claim 5, wherein the first polysilicon gate layer includes a first extension segment, wherein the first extension segment of the first polysilicon gate layer and the first polysilicon gate layer are collaboratively formed as a closed polysilicon gate layer, and the closed polysilicon gate layer surrounds the second polysilicon gate layer.

12. The erasable programmable non-volatile memory cell as claimed in claim 5, wherein when a program action is performed, the source line a ground voltage, the word line receives an on voltage, the bit line receives a program voltage, and the assist line receives an assist voltage higher than or equal to the program voltage, wherein when the program action is performed, a channel hot electron effect is generated, and a plurality of electrons are attracted by the assist voltage and injected into the first polysilicon gate layer of the first gate structure.

13. The erasable programmable non-volatile memory cell as claimed in claim 5, wherein when an erase action is performed, the source line a ground voltage, the word line receives an on voltage, the bit line receives an erase voltage, and the assist line receives an assist voltage lower than or equal to the ground voltage, wherein when the erase action is performed, a channel hot hole effect is generated, and a plurality of holes are attracted by the assist voltage and injected into the first polysilicon gate layer of the first gate structure.

14. The erasable programmable non-volatile memory cell as claimed in claim 5, wherein when an erase action is performed, the source line a ground voltage, the word line receives an off voltage, the bit line receives an erase voltage, and the assist line receives an assist voltage lower than or equal to the ground voltage, when the erase action is performed, a band-to-band hot hole effect is generated, and a plurality of holes are attracted by the assist voltage and injected into the first polysilicon gate layer of the first gate structure.

15. The erasable programmable non-volatile memory cell as claimed in claim 5, wherein when a read action is performed, the source line a ground voltage, the word line receives an on voltage, the bit line receives a read voltage, and the assist line receives a voltage between the ground voltage and the read voltage, wherein when the read action is performed, a read current is generated between the bit line and the source line, and a storage state of the memory cell is determined according to a magnitude of the read current.

16. The erasable programmable non-volatile memory cell as claimed in claim 1, wherein the first merged doped region contains a first ion implantation region and a second lightly doped drain region, and the second merged doped region contains a second ion implantation region and a third lightly doped drain region.

17. The erasable programmable non-volatile memory cell as claimed in claim 16, wherein a first distance between the second lightly doped drain region and the first lightly doped drain region is greater than a second distance between the first lightly doped drain region and the third lightly doped drain region.

18. The erasable programmable non-volatile memory cell as claimed in claim 16, wherein the second lightly doped drain region is formed by using a lightly doped drain process of a medium voltage production procedure, and the first lightly doped drain region and the third lightly doped drain region are formed by using a lightly doped drain process of a low voltage production procedure.

19. The erasable programmable non-volatile memory cell as claimed in claim 16, wherein a doping depth of the second lightly doped drain region is deeper than or equal to a doping depth of the first lightly doped drain region, and the doping depth of the second lightly doped drain region is deeper than a doping depth of the third lightly doped drain region.

20. The erasable programmable non-volatile memory cell as claimed in claim 16, wherein a doping concentration of the second lightly doped drain region is lower than or equal to a doping concentration of the first lightly doped drain region.
